(19) United States
(12) Patent Application Publication
(10) Pub. No.: US 2021/0183608 A1
(43) Pub. Date: Jun. 17, 2021

(54) PHOTON-INDUCED ION SOURCE

(71) Applicant: FEI Company, Hillsboro, OR (US)

(72) Inventors: Kun LIU, Portland, OR (US); Gregory A. SCHWIND, Portland, OR (US); Sean KELLOGG, Portland, OR (US); Jorge FILEVICH, Portland, OR (US)

(73) Assignee: FEI Company, Hillsboro, OR (US)

(21) Appl. No.: 16/717,043

(22) Filed: Dec. 17, 2019

(51) Int. Cl. H01J 27/24

(52) U.S. Cl. CPC H01J 27/24

(57) ABSTRACT

Apparatuses and methods for an optical induced ion source are disclosed herein. An example apparatus at least includes an ionization volume arranged to receive a gas and first optical energy, the first optical energy to ionize the gas, and a channel formed between a first membrane and a second membrane, the first membrane having at least a transparent portion and the second membrane including an aperture, where the gas is provided to the ionization volume through the channel, the ionization volume formed inside the channel and adjacent to the aperture, and where the first optical energy ionizes the gas after passing through the at least transparent portion of the first membrane.

### FIELD OF THE INVENTION

The invention relates generally to ion sources, and specifically to photon-induced nano-aperture ion sources for use in charged particle systems.

### BACKGROUND OF THE INVENTION

There are many types of ion sources available today, such as liquid metal ion sources, plasma-based ion sources, and sputter-based ion sources, to provide a few examples. While the liquid metal ion sources (usually in a Gallium flavor) may typically be used in many applications, there is a desire for ion sources that provide higher brightness and lower energy spread. Numerous attempts have been made at meeting these goals over the years, as indicated by the development of so many different types of ion sources, but there tend to be drawbacks and/or complicated engineering problems encountered. For example, plasma-based ion sources (either RF or ICP types) provide high brightness and high current, but typically require complicated power and thermal management design.

### SUMMARY

Apparatuses and methods for an optical induced ion source are disclosed herein. An example apparatus at least includes an ionization volume arranged to receive a gas and first optical energy, the first optical energy to ionize the gas, and a channel formed between a first membrane and a second membrane, the first membrane having at least a transparent portion and the second membrane including an aperture, where the gas is provided to the ionization volume through the channel, the ionization volume formed inside the channel and adjacent to the aperture, and where the first optical energy ionizes the gas after passing through the at least transparent portion of the first membrane.

Another example includes a first membrane having a transparent portion, a second membrane having an aperture, a channel formed between the first and second membranes, a gas source coupled to provide gas to the channel, and first and second optical sources coupled to provide first and second optical energies, respectively, through the transparent portion to excite and ionize the gas to form ions, the ions emitted out of the aperture, where the first optical energy excites the gas to an intermediate energy state, and where the second optical energy ionizes the excited gas.

### BRIEF DESCRIPTION OF THE DRAWINGS

FIG. 1A is an example focused ion beam (FIB) system 100A including a photon-induced NAIS in accordance with an embodiment of the present disclosure.

FIG. 1B is an example dual-beam (DB) system 100B including a photon-enabled NAIS in accordance with an embodiment of the present disclosure.

FIG. 1C is an example triple-beam (TriBeam) system 100C including a photon-induced NAIS in accordance with an embodiment of the present disclosure.

FIG. 2 is an example photon-enabled NAIS 204 in accordance with an embodiment of the present disclosure.

FIG. 3 is an illustration of an example photon-induced NAIS 304 in accordance with an embodiment of the present disclosure.

FIG. 4 is an example illustration of a NAIS 404 in accordance with an embodiment of the present disclosure.

FIG. 5 is an example illustration of NAIS 504 in accordance with an embodiment of the present disclosure.

FIG. 6 is an example illustration of a NAIS 604 in accordance with an embodiment of the present disclosure.

FIG. 7 is an illustration of NAIS 704 in accordance with an embodiment of the present disclosure.

Like reference numerals refer to corresponding parts throughout the several views of the drawings.

### DETAILED DESCRIPTION OF EMBODIMENTS

Embodiments of the present invention are described below in the context of a photon-induced nano-aperture ion source (NAIS). The photon-induced NAIS can be included in various charged particle systems that include an ion column, such as a focused ion column, and the photon-induced NAIS may provide a high brightness source, at least compared to a Gallium-based liquid metal ion source. However, it should be understood that the methods described herein are generally applicable to a wide range of different ion beam methods and apparatus, including both cone-beam and parallel beam systems, and are not limited to any particular apparatus type, beam type, object type, length scale, or scanning trajectory

As used in this application and in the claims, the singular forms “a,” “an,” and “the” include the plural forms unless the context clearly dictates otherwise. Additionally, the term “includes” means “comprises.” Further, the term “coupled” does not exclude the presence of intermediate elements between the coupled items.

The systems, apparatus, and methods described herein should not be construed as limiting in any way. Instead, the present disclosure is directed toward all novel and non-obvious features and aspects of the various disclosed embodiments, alone and in various combinations and sub-combinations with one another. The disclosed systems, methods, and apparatus are not limited to any specific aspect or feature or combinations thereof, nor do the disclosed systems, methods, and apparatus require that any one or more specific advantages be present or problems be solved. Any theories of operation are to facilitate explanation, but the disclosed systems, methods, and apparatus are not limited to such theories of operation.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, methods, and apparatus can be used in conjunction with other systems, methods, and apparatus. Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art.

In some examples, values, procedures, or apparatuses are referred to as “lowest”, “best”, “minimum,” or the like. It will be appreciated that such descriptions are intended to indicate that a selection among many used functional alternatives can be made, and such selections need not be better, smaller, or otherwise preferable to other selections.

Ion sources for focused ion beam (FIB) columns with higher brightness and lower energy spread than traditional Gallium (Ga) ion sources are very desirable. High brightness provides better performance in imaging, processing and material analysis, for example. While higher brightness is desirable, even a source having equal (or even a little less) brightness is also desirable, especially since the ion beam is not gallium, such as a noble gas. Prior attempts at a higher brightness source resulted in the development of a nano-aperture ion source (NAIS). The NAIS is composed of an electron beam system that provides an electron beam to ionize neutral gas in a reaction volume, a gas delivery system to deliver a gas to ionize, and (3) an aperture assembly. The aperture assembly includes two membranes that are separated by a 100-1000 nm gap. The aperture assembly confines the gas precursor in a small volume, e.g., the reaction volume, for ionization and ion extraction, which are then emitted to ion optics to form ion beam. The ion beam may then be used for imaging and/or processing, for example.

In addition to high brightness and low energy spread, a NAIS can also switch ion species during operation, which is very desirable in many applications. More importantly, a NAIS can be applied in some critical technology areas such as III-V semiconductors where Ga ion sources could be a source of device contamination. With all above advantages, NAIS may become very valuable and could have huge marketing opportunities. During implementation of a conventional NAIS system, some challenges were encountered. These challenges at least include the following: (1) the e-beam system needs to be electrically floated on the ion beam energy, which makes engineering difficult; (2) the gas delivery system should also be floated on the ion beam voltage to avoid potential arcing via high pressure gas inside the delivery line, which also makes engineering challenging; (3) the e-beam system requires a good vacuum to run and maintain, which becomes very hard when a high pressure gas is delivered to the nano-aperture device and leaks through the aperture into the space where the e-beam system resides (a sudden poor vacuum condition could kill the e-system); (4) a robust nano-aperture device is very difficult to fabricate; (5) gas ionization rate from an impacted electron beam is low and high electron beam current is required to produce sufficient ions, which is impractical in some high throughput applications; and (5) electron impact ionization results in a beam of ions having multiple charge states, for example 94% Ar+, 5% Ar++, and 1% Ar+++, and these components will unfortunately become separated in the beam line in the presence of even weak magnetic fields, leading to a multiplicity of ion beams at the sample. Considering the listed challenges, an improved NAIS is desirable.

One solution to reduce or eliminate one or more of the above-identified challenges is to use an optical source for ionizing the gas. To discuss a few of the challenges, replacing the e-beam system with the optical source alleviates the challenges with electrically floating the e-beam system on the ion producing system, the formation of multiple charge states, and reduces the vacuum constraints since the optical energy can be delivered through one or more transparent windows. The photon-induced NAIS system allows for the formation of desired ion species under better control and with improved/easier managed environmental, e.g., vacuum, conditions.

In general, the photon-induced NAIS will include two membranes separated by a gap with one membrane including at least one optically transparent window and the other membrane including an aperture. It will be appreciated by those skilled in the art that the term membrane is not limiting to thin flat electrodes, and that membrane can also include other electrode shapes, such as rings, discs, cones, plates, and combinations thereof. The at least one optically transparent window allows for introduction of one or two beams of optical energy for ionization of a gas, and the aperture is for emitting generated ions. The gap between the two membranes provides a channel for introduction of the gas to the reaction volume, which may also be referred to as the ionization volume or ionization region. The ionization volume may be adjacent to the aperture and comprise a volume of the channel between the aperture and other membrane where the ionization of the gas occurs. A potential difference established between the two membranes may induce the ions to drift toward the aperture for extraction into the ion beam column. Emitted ions may be attracted to ion optics, which form the ions into an ion beam for focusing and providing to a sample for imaging, milling, etching and/or deposition. The etching and deposition may be performed with a process gas present at the surface of the sample.

In some embodiments optical energy may be introduced into the ionization volume by more than one optical source. In such an embodiment, one optical source may provide optical energy at an intensity and energy to excite the gas to an intermediate state. This optical energy may be referred to as the excitation energy that is provided by an excitation source. A second optical source may provide optical energy at an intensity and energy to further excite the gas from the intermediate state to a desired ionization state. This optical energy may be referred to as the ionization energy that is provided by an ionization source. In some embodiments, both the excitation and the ionization sources are lasers. The lasers may be operated in either continuous wave (CW) or pulsed wave (PW) regimes. To note, by first exciting the gas with one source then ionizing the gas with another source, the number of charge states generated may be reduced to a single desired charge state in most, if not all, embodiments. It should be noted, however, that multiple optical sources are not necessary and the use of a single optical source to ionize the gas is within the scope of the present disclosure.

Some of the disclosed techniques use high power lasers to excite, ionize and produce ions from gas species in a small volume, followed by ion extraction to form an ion beam. The laser could operate in either CW mode or pulse mode, where lasers operated in pulse mode provide higher energy density that could ionize gas more efficiently. In general, a broad excitation laser beam illuminates gas inside the nano-aperture device and an ionization laser beam is focused into a small spot (e.g., 1 um in diameter) near the nano-aperture. Gas molecules inside a small volume near the aperture, which is determined by the focused laser beam and the gap between two membranes, are excited to excited states by the excitation laser and then ionized by the ionization laser. Ions produced in this small volume are extracted/transported out of the nano-aperture by a small potential between both plates and then form an ion beam via the downstream ion optics. With an optical window to block gas leakage, gas density inside the nano-aperture device should be higher than that in current electron-impacted NAIS assuming a similar geometry configuration. In addition, space above the aperture device should have better vacuum condition due to no gas leakage into it (the window prevents leakage). Considering gas ionization rate from laser is much higher than from electrons, thus higher ion current is expected in such photon-induced ion source.

Advantages of the disclosed techniques at least include: (1) the e-beam system is not a requirement, there would be no concerns about floating the e-beam system on ion beam energy; (2) the upper space (above the ion source) becomes available, multi-gas tanks can be installed inside and safely floated on the ion beam energy, laser components can also be installed in this space; (3) there is no critical vacuum constrain for the upper space; (4) gas ionization rate from high density photons (laser) is much higher than that from electrons leading to high ion beam current; and (5) ionization with laser beams may ensure that only singly ionized species are produced in and emitted from this source.

As will be discussed below, numerous examples of the photon-induced NAIS are possible, and all examples are within the scope of the present disclosure. For example, instead of a gas source providing a gas to the channel, a solid source may be housed within the photon-induced NAIS that provides a partial pressure of gas for exciting and ionizing. In such an embodiment, the solid source is disposed so that the optical energy can be delivered to the surface of the solid source or adjacent to where the gas may flow. Other examples include different arrangements for delivery of the optical energy and/or ionization region formation.

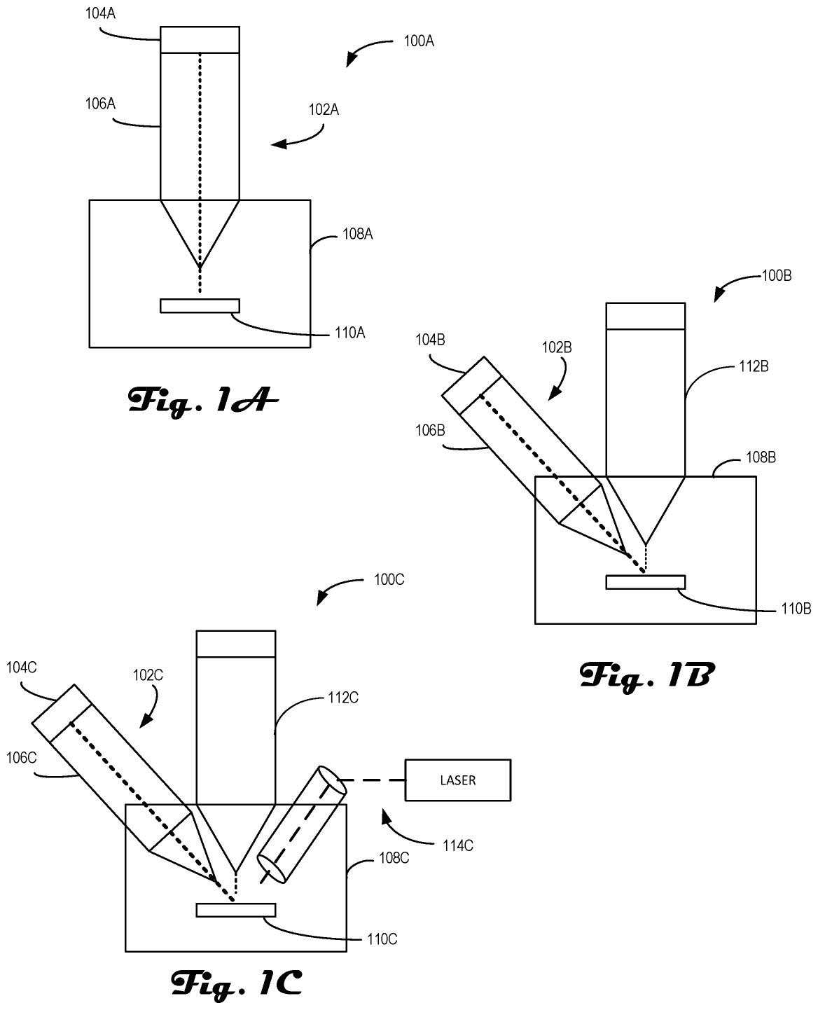

FIG. 1A is an example focused ion beam (FIB) system 100A including a photon-induced NAIS in accordance with an embodiment of the present disclosure. The FIB 100A includes an ion column 102A that delivers ions from an ion source 104A to a sample 110A. The ion column 102A includes ion optics 106A to form, shape, alter, manipulate the ion beam provided by ion source 104A prior to the ion beam reaching the sample 110A. The sample 110A and at least a portion of the ion column 102A are enclosed in a vacuum chamber 108A that provides a low pressure environment for FIB milling and/or imaging. While not shown, one or more gasses may be delivered to the sample 110A surface so that ion-induced deposition and/or etching may also be implemented.

The ion optics 106A includes one or more lenses for manipulating the ion beam within the ion column 102A. For example, ion optics 106A may include a gun lens, an objective lens and other components, such as beam blankers, beam defining apertures, and scanning deflectors. The combination of these components allows the ion beam to be delivered at various energies and/or currents and moved across a surface of the sample 110A so that specific areas of the sample 110A may be imaged, milled, etched, and/or material deposition performed.

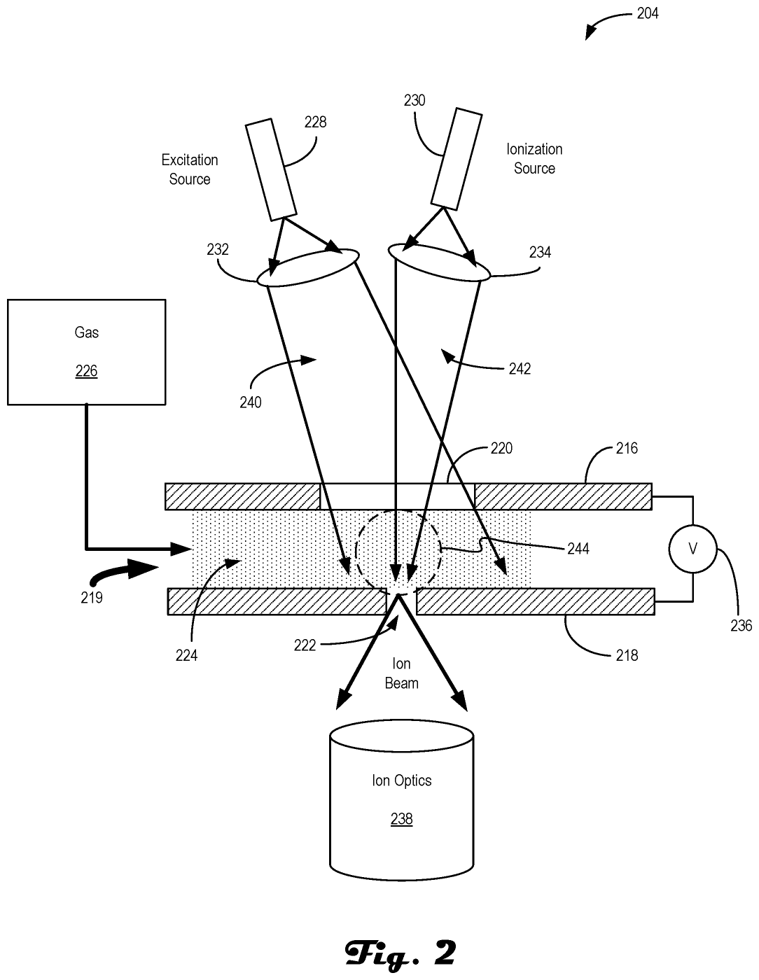

The ion source 104A provides ions to the ion optics 106A that have been ionized due to high intensity optical energy. The ions are generated, for example, by focusing high intensity optical energy onto a small volume of gas, e.g., an ionization volume, that is then ionized due to the optical energy. Once ionized, the ions emit out of a small aperture in a membrane of the ion source 104A and are collected by the ion optics 106A. In some embodiments, a potential difference between the membrane and a second membrane may promote the movement of the ions toward and out of the aperture. The second membrane is at least partially transparent for transmission of the optical energy. Additionally, the first and second membranes are arranged to form a channel for gas delivery. See at least FIG. 2 for an example ion source in accordance with the disclosure. In some embodiments, the gas in the channel is illuminated with two different optical energies, a first optical energy to excite the gas to an intermediate state (e.g., from an excitation optical source) and a second optical energy to ionized the excited gas (e.g., from an ionization optical source). The first and second optical sources may be lasers, for example, of different intensities and/or wavelengths.

FIG. 1B is an example dual-beam (DB) system 100B including a photon-enabled NAIS in accordance with an embodiment of the present disclosure. The DB 100B includes an ion column 102B and an electron column 112B, along with the other components discussed with respect to FIB 100A, which, for sake of brevity, will not be discussed again. The electron column 112B, or SEM column, is included to provide additional capabilities with imaging a sample 110B. The ion column 102B, like the ion column 102A, incudes a photon-induced NAIS 102B to generate and provide an ion beam.

FIG. 10 is an example triple-beam (TriBeam) system 100C including a photon-induced NAIS in accordance with an embodiment of the present disclosure. The TriBeam 100C is an extension of the DB 100B in that it includes a laser “column” 114C in addition to the FIB and electron columns 102C and 112C, respectively. The addition of the laser column 114C allows for flexibility in sample processing, such as an increase in material removal rate with a laser provided by the laser column 114C that can be augmented with more gentle processing by the FIB column 102C. While the laser column 114C is shown access a sample 110C through the vacuum chamber 108C, in other embodiments, the laser column 114C may process a sample in a separate, but connected, chamber.

In general, each of the systems 100A, 100B and 100C include a photon-induced NAIS to overcome or reduce the challenges discussed above so that a brighter ion source may be implemented to provide improved imaging and processing capabilities.

FIG. 2 is an example photon-enabled NAIS 204 in accordance with an embodiment of the present disclosure. The photon-enabled NAIS 204 (NAIS 204 for short) is one example of the ion sources 104A-104C implemented in systems 100A-100C. In general, the NAIS 204 provides a desired species of ions for an ion column implemented in any charged particle beam system, such as a FIB, a DB or a TriBeam system, and may be used to mill, etch, deposit material on and/or image samples. The NAIS 204 is a high brightness ion source that improves the various uses as discussed.

The NAIS 204 at least includes a first membrane 216, a second membrane 218, a gas source 226, first and second optical energy sources 228, 230, and a bias source 236. These components may be arranged to form a restricted volume for ion generation, e.g., ionization volume 244, using one or both of the optical energy sources 228, 230. Some of the generated ions are emitted via an aperture 222, e.g., an ion output aperture, formed in the second membrane 218 and are collected by ion optics 238. The ion optics 238 are generally part of an ion column, not necessarily the NAIS 204, but are included to complete the picture of providing an ion beam using ions generated by the NAIS 204.

The first membrane 216 may have at least a portion that is transparent to optical wavelengths used to form the ions. For example, first membrane 216 includes transparent portion 220, which may also be referred to herein as window 220. While transparent portion 220 is shown to be located at a center location of first membrane 216 and to span a third of the shown length, such arrangement is only an example and other arrangements are contemplated. For example, the transparent portion 220 may be located at other locations of the first membrane 216, or it may form the entirety of the first membrane 216. The second membrane 218 includes the aperture 222 and is arranged to form the ionization volume 244 between the two membranes. The ionization volume 244 is where the optical energy is provided for generating the ions, and it may have a desired pressure of gas 224 to enable ionization. In general, the ionization volume 244 is defined by the gap between the two membranes 216, 218 and the exposure area of at least optical source 230, which may be manipulated by one or more lenses.

The shape of the membranes 216 and 218, from a plan view, may be formed to fit inside of an enclosure mounted to or incorporated into an ion column, such as ion columns 102A-1020. Examples shapes include circular, rectangular, square, etc. In some embodiments, sidewalls may be disposed on the edges of the membranes 216 and 218 to form an enclosure for the channel 219 and the ionization volume 244. In some embodiments, the membranes 216 and 218 may each have a thickness about 100-200 nm and the channel 219 between the two membranes may be up to a few millimeters. In some embodiments, the aperture 222 may have an diameter of around 50-200 nm. Of course, other dimensions are possible and contemplated and may only be limited by the ability to provide a gas at the ionization volume at a pressure that provides an efficient ionization cross-section. The membranes may be formed from silicon or silicon nitride using a MEMS process, for example, and the window 220 may be formed from silicon dioxide or quartz, to name a few examples. Additionally or alternatively, inside surfaces of membranes 216 and 218 may be reflective (not shown), at least to the wavelengths of optical sources 228 and 230, so that incident radiation is reflected inside channel 219. The reflectance may assist with illumination of the ionization volume 244, and may reduce or prevent the optical energy from damaging the membranes.

A gas source 226 provides a desired gas to the volume 244. The gas source 226 may be disposed outside of the NAIS 204 but be fluidly coupled to provide a desired gas 224 to the channel 219. In some embodiments, the type or species of gas 224 may be switched to different types/species so that different ions are provided to ion optics 238. Example gasses include argon, xenon, neon, krypton, for noble species micromachining applications; oxygen, nitrogen, or other reactive species for surface chemical functionalization applications; or the vapors of heated iodine, cesium, or other alkali metals for surface analysis by secondary ion mass spectrometry.

First and second optical energy source 228, 230 may be arranged to provide respective optical energies to the ionization volume 244 via the window 220 and adjacent to the aperture 222. The optical energies may be provided via respective lenses 232, 234 selected to provide a desired optical beam spot size in the ionization volume 244. For example, source 228 may be provided to a large area so that a large volume of gas is exposed to the excitation energy. On the other hand, the source 230 may be focused to a small area, e.g., 1 μm, so that the ionization efficiency is increased. Optical source 228 provides optical energy to excite the gas to an elevated energy state. The source 228, which can be referred to as the excitation source, may energize the gas to enhance eventual ionization without promoting ionization. The gas 224 in the volume 244 may then be provided a second optical energy from optical source 230, which provides energy to cause the excited gas to ionize. Optical source 230 may be referred to as the ionization optical source. Once ionized, a voltage difference between the first and second membranes 216, 218 may promote the ionized gas to drift toward the aperture 222 where they can be emitted to the ion optics 238 for formation of an ion beam, such as a focused ion beam. The voltage difference is provided by coupling a voltage source 236 between the first and second membranes, which may be a DC or an AC source.

In some embodiments, excitation and ionization sources 228 and 230 are lasers, such as solid state laser. Of course, other laser types are contemplated and available as well. For example, to ionize a Rubidium atom a photon of 4.2 eV energy is needed, corresponding to 296 nm wavelength, which is conventionally a difficult wavelength to generate. Instead of using this ultraviolet photon, a first excitation step can be made using a photon of 2.4 eV, corresponding to a 516 nm wavelength laser (provided by excitation source 228) to excite Rb to the 5p2P° level, followed by a second photon of 1.8 eV energy, corresponding to a 688 nm wavelength laser (provided by ionization source 230) to ionize the Rb atom. The same can be achieved using Cs atoms, instead of a direct ionization from the ground state (photons of 318 nm wavelength corresponding to 3.89 eV) a two-step process, exciting the atom using a 689 nm wavelength (1.8 eV) followed by a 592 nm wavelength photon (2 eV), is implemented.

In operation, a gas is provided to the channel 219 by the gas system 226. The gas will flow into the ionization volume 244 and be irradiated by the first and second optical sources so that ions are formed. The ions, due to their charge, will be induced to move away from the first membrane 216 toward the second membrane 218 under the influence of the potential difference established by voltage source 236. Some of the ions will eventually leave the volume through the aperture 222 to be formed into a focused ion beam by the ion optics 238. In some embodiments, the gas pressure in the ionization volume 244 is around 1 atm. At this pressure and with the ionization source 230 providing 1 mJ pulses at a rate of 500 kHz (using a 532 nm wavelength laser), around 6 □A of ions may be provided by NAIS 204 assuming an ionization rate of 10% and ion extraction efficiency of 10%. With adding the excitation source 228 (532 nm wavelength laser or others operating in either CW or pulsed mode), comparable or more ion beam currents can be produced, while an ionization laser source of lower pulse energy and repetition rate can be used. In general, the excitation and ionization techniques disclosed herein may require either pulsed lasers to provide multi photon ionization or very short wavelengths for CW lasers. Multiple wavelengths to excite and ionize are possible but they likely need to be pulsed and coincident in time due to the short lived nature of the electronic states we are dealing with.

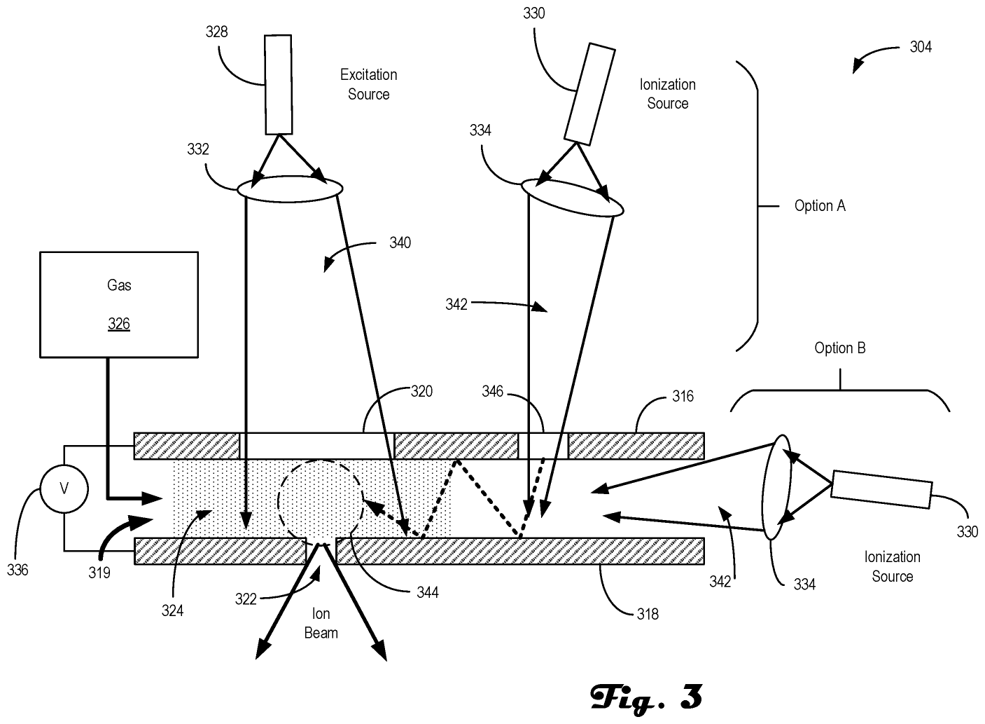

FIG. 3 is an illustration of an example photon-induced NAIS 304 in accordance with an embodiment of the present disclosure. The NAIS 304 has many, if not all, of the same components as NAIS 204, but shows a number of different arrangements for the ionization optical source and how the ionization energy can be introduced to the ionization volume 344. In general, the NAIS 304 can be implemented in any type of charged particle beam system, such as a FIB, DB or TriBeam, as shown in FIGS. 1A-1C, respectively. The NAIS 304 is used to generate ions that are provided to a surface of a sample for imaging, milling, gas assisted etching and/or gas assisted deposition.

For sake of brevity, only the differences of NAIS 304 over NAIS 204 will be discussed in detail. Specifically, the ionization optical energy may be introduced to the ionization volume 344 by one of two different orientations over NAIS 204. For example, the ionization optical energy may be provided through a second transparent window 346 if Option A is implemented. On the other hand, Option B may be implemented, which arranges the ionization optical energy to be provided to the ionization volume 344 via the channel 319 formed between the first and second membranes 316, 318. In either embodiment, the inside surfaces of the first and second membranes may be reflective at least to the wavelengths of the introduced optical energies so to promote concentration of the optical energy in the ionization volume 344 instead of incurring losses through interaction with the surfaces of the membranes.

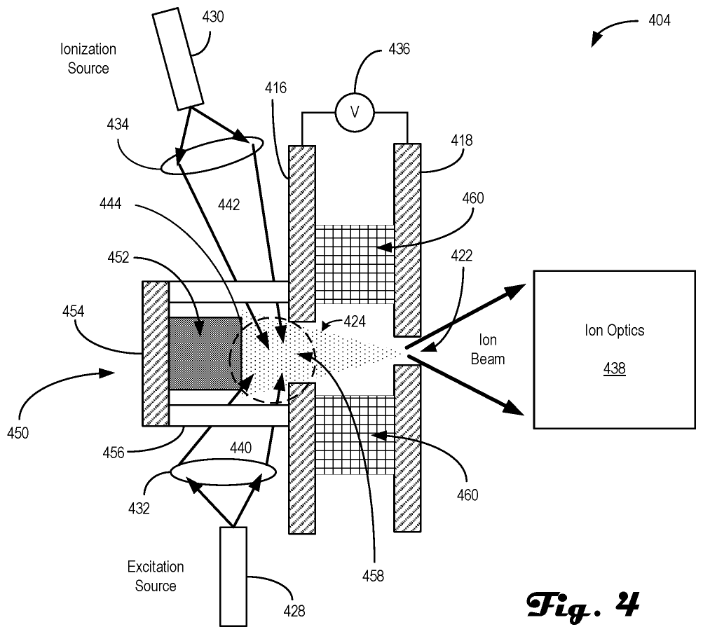

FIG. 4 is an example illustration of a NAIS 404 in accordance with an embodiment of the present disclosure. The NAIS 404 is yet another example NIAS source that can be implemented in systems 100A through 100C, for example. In general, the NAIS 404 includes a solid gas source disposed in a cell coupled to the ionization volume via a second aperture. This second aperture allows the gas and ions to be provided to the ion output aperture 422. For brevity's sake, only the differences between NAIS 404 and NAIS 202 will be discussed in detail.

The NAIS 404 includes a solid gas precursor cell 450 coupled to the first membrane 416. The solid gas precursor cell 450 houses a solid fuel source 542, and is formed by a (optionally removeable) cover 454 (with heating function) and one or more transparent sides 456. Due to vapor pressure of the solid fuel source, and the vacuum environment, vapor of the solid fuel source 452 is produced inside the cell 450. The higher the vapor pressure of the solid fuel source, the more gas precursors are generated inside the cell 450. To increase gas precursor density or pressure inside the cell 450, laser ablation using the excitation source 428 or thermally heating using the cover 454 can be applied to the solid source precursor. Ions may be generated by providing excitation and ionization optical energies from optical sources 428 and 430, respectively. Generated ions may then be induced to drift toward output aperture 422 through fuel cell aperture 458. The potential difference inducing the drift of the ions may be established between the first and second membranes 416 and 418 as previously described. Ions that emit out of output aperture 422 may then be formed into a focused ion beam via ion optics 438. To help confine the gas and ions within the channel between the membranes, structural barrier(s) 460 may be disposed between the two membranes adjacent to the apertures 458 and 422.

The solid gas precursor cell 450 eliminates the need for coupling gas canisters via gas lines to a NAIS, which should simplify ion column design and tool placement. However, the use of a solid precursor 452 may limit the available ion species and additionally reduce or eliminate the ability to provide different ion species by a single ion column. Regardless, depending on the use of the NAIS 404, the simplicity of the solid precursor based system may negate any other concerns. Example sold precursors include Cesium, lithium, rubidium, iodine and buckminsterfullerene.

It should be noted that in the NAIS 404, the ionization volume 444 may be formed between the fuel source 452, the aperture 458 and the exposure volume of the ionization source 430. In some embodiment, the ionization volume 444 may extend into the volume between the membranes adjacent to the apertures 458, 422.

While NAIS 404 includes two membranes 416, 418, in other embodiments, only one membrane may be included, such as membrane 416, for providing the output ions. In such an embodiment, a potential difference is formed between a side of the fuel container and the aperture for promoting movement of the ions toward the aperture. Additionally, in such an embodiment, the second aperture would also be the output aperture.

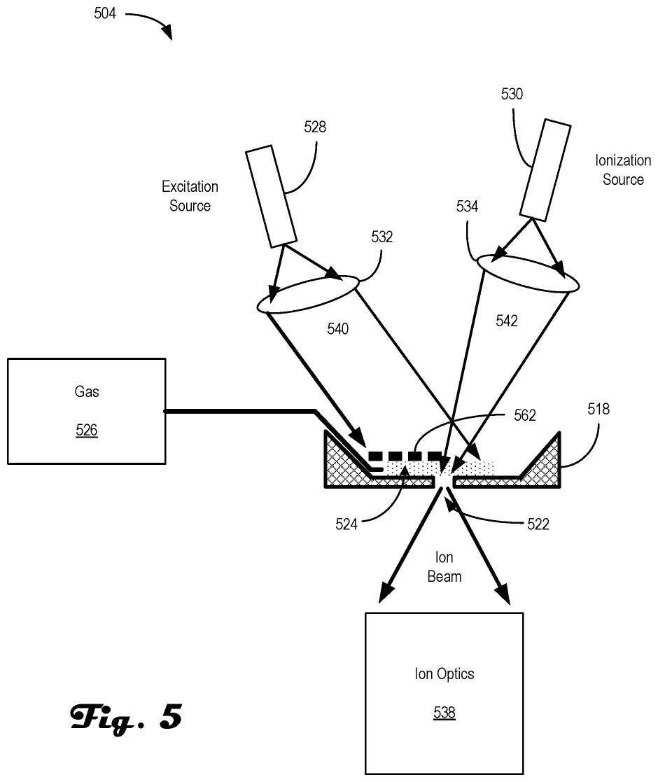

FIG. 5 is an example illustration of NAIS 504 in accordance with an embodiment of the present disclosure. The NAIS 504 is yet another example of a photon-induced NAIS that can be implemented in any of the systems 100A through 100C. In general, NAIS 504 generates ions using optical energy and provides the ions to ion optics for the formation of a focused ion beam for use in imaging, milling, ion induced etching and/or material deposition. In some aspects, the NAIS 504 may be easier to fabricate than NAISs 204-404As due to having fewer components. As previous, only the differences between NAIS 504 and the previously discussed NAIS systems will be described in detail.

The NAIS 504 includes one membrane 518 with the aperture 522. Instead of a first membrane that includes a transparent window, NAIS 504 includes a grid 562 for forming an ionization volume similar to that discussed with regards to NAISs 204-404. A potential may be established between the grid 562 and the membrane 518 to promote drift of ions toward aperture 522. In some embodiments, the gas 534 is provided in short duration, high pressure pulses to form an instance of high pressure gas in an ionization volume. To generate ions, the pressure of the gas in the ionization volume should be high enough to form an efficient ionization cross-section.

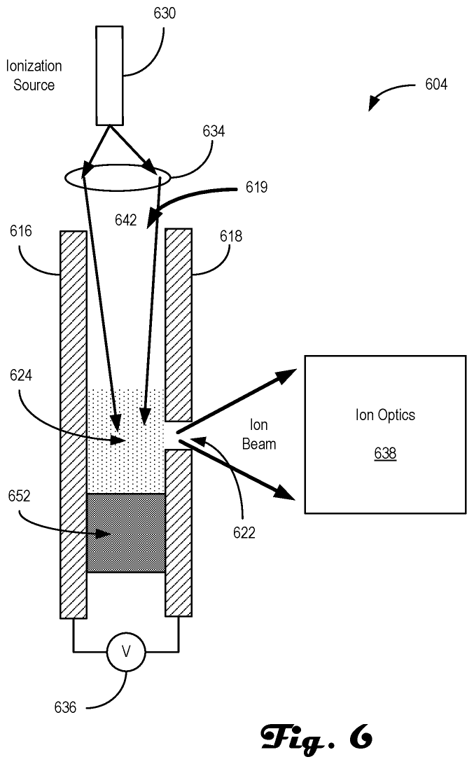

FIG. 6 is an example illustration of a NAIS 604 in accordance with an embodiment of the present disclosure. The NAIS 604 is yet another example of a photon-induced NAIS that can be implemented in any of the systems 100A through 100C. In general, NAIS 604 generates ions using optical energy and provides the ions to ion optics for the formation of a focused ion beam for use in imaging, milling, ion induced etching and/or material deposition. Additionally, NAIS 604 is a variation of NAIS 404 in that a solid source gas precursor is used to provide the gas supply. However, instead of disposing the solid source gas precursor in a separate cell attached to one of the membranes, the solid source gas precursor of NAIS 604 is disposed between the two membranes.

The NAIS 604 includes first and second membranes 616, 618, with second membrane 618 having an aperture 622. The NAIS 604 further includes a solid precursor source 652 disposed between the two membranes 616, 618. As described above gas precursors 624 from the solid precursor source 652 can be produced adjacent to the aperture 622, which is illuminated with ionization energy to form ions. The ionization energy may be provided through the channel 619 formed between the two membranes and may be incident on the gas 624 adjacent to the aperture 622. A potential established between the first and second membranes will induce ions to drift toward the aperture 622 for emission to ion optics 638.

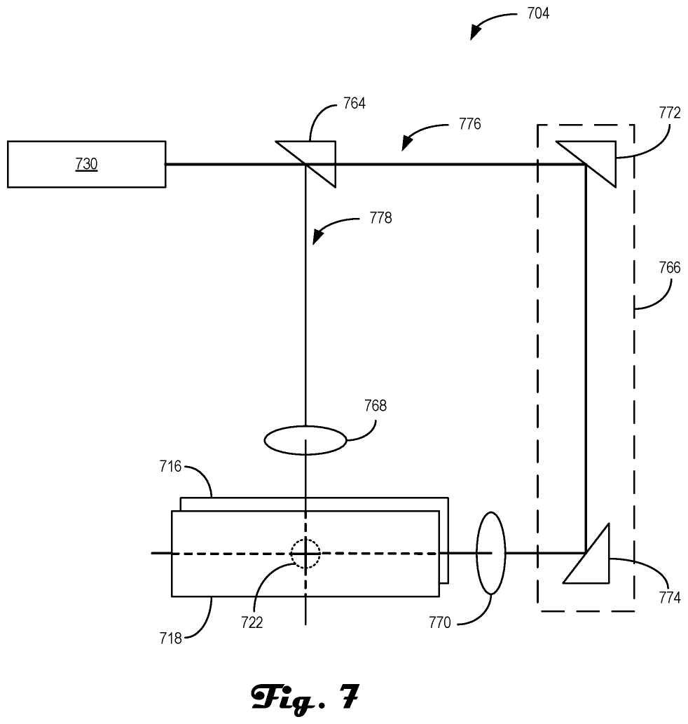

FIG. 7 is an illustration of NAIS 704 in accordance with an embodiment of the present disclosure. NAIS 704 is another example of an ion source that may be implemented in system 100A-100C, for example. In general, the NAIS 704 includes a laser that crosses with a delayed version of itself in an area adjacent to aperture 722 to generate ions. By crossing the laser with itself, the ionization energy can be confined to the ionization volume adjacent the aperture 722 while the optical energy is less everywhere else. By reducing the energy everywhere else, the potential for damage to the NAIS 704 outside of the ionization volume is reduced or eliminated. While other components of the NAIS 704 are not shown, such as a gas source, a voltage source for providing a potential difference across the membranes, etc., such components are included in the NAIS 704 as needed and are not shown for brevity's sake.

One embodiment of the NAIS 704 includes an ionization optical source 730, first and second membranes 716 and 718, and an optical delay 766. The ionization source 730 provides optical energy to beam splitter 764, which splits the beam into two branches 776 and 778. Branch 778 is directed toward the membranes 716, 718 through lens 768, and branch 776 is directed toward delay 766. Delay 776 includes two mirrors 772 and 774 for routing the optical energy of branch 776 back toward the membranes 716, 718 via lens 770. In some embodiments, branch 776 may approach the membranes 716, 718 in a direction orthogonal to branch 778. Of course, other orientations between the two branches at the ionization volume are possible and contemplated herein. The two branches 776, 778 enter the channel, e.g., gap, between the two membranes and interact with each other in a volume adjacent the aperture 722, e.g., the ionization volume. The interaction, based on the delay, should be additive so that an optical intensity obtained is strong enough to induce ionization of a gas present in the ionization volume.

While the NAIS 704 shows one arrangement for the optics and delay, there are many other arrangements capable of providing the same optical result at the ionization volume, which are contemplated herein. It should be understood that the arrangement of NAIS 704 is not limiting.

The embodiments discussed herein to illustrate the disclosed techniques should not be considered limiting and only provide examples of implementation. In general, the techniques disclosed herein are directed toward photon-induced ion beams formed from localized ionization regions provided with a desired ionizing gas. Those skilled in the art will understand the other myriad ways of how the disclosed techniques may be implemented, which are contemplated herein and are within the bounds of the disclosure.

What is claimed is:

1. An apparatus comprising:
an ionization volume arranged to receive a gas and first optical energy, the first optical energy to ionize the gas; and
a channel formed between a first membrane and a second membrane, the first membrane having at least a transparent portion and the second membrane including an aperture, wherein the gas is provided to the ionization volume through the channel, the ionization volume formed inside the channel and adjacent to the aperture, and wherein the first optical energy ionizes the gas after passing through the at least transparent portion of the first membrane.

2. The apparatus of claim 1, wherein the first optical energy is provided by a first optical source.

3. The apparatus of claim 2, wherein the first optical source is a laser.

4. The apparatus of claim 1, further comprising a second optical source to provide second optical energy, the second optical energy incident on the gas and of an optical energy that excites the gas to an intermediate state.

5. The apparatus of claim 4, wherein the second optical source is a laser.

6. The apparatus of claim 4, wherein the second optical energy is provided through the transparent portion.

7. The apparatus of claim 4, further including a second transparent portion in the first membrane, wherein the second optical energy is provided through the second transparent portion.

8. The apparatus of claim 4, wherein the second optical energy is provided through the channel.

9. The apparatus of claim 1, further comprising a gas injection system arranged to provide the gas to the channel.

10. The apparatus of claim 1, further comprising ion optics arranged to receive ions emitted from the aperture.

11. The apparatus of claim 1, further comprising a voltage source coupled to the first and second membranes and providing a potential difference between the first and second membranes to induce the ions to move toward the aperture.

12. The apparatus of claim 1, wherein surfaces of the first and second membranes that face the channel are reflective.

13. The apparatus of claim 1, wherein the first optical energy is provided in a pulsed or continuous form.

14. The apparatus of claim 1, further including an optical splitter and an optical delay, wherein the first optical energy is provided to the ionization volume by the optical splitter and by the optical delay so that the first optical energy interacts with a delayed instance of the first optical energy at least in the ionization volume.

15. The apparatus of claim 14, wherein the optical delay includes two mirrors.

16. The apparatus of claim 14, wherein the delayed instance of the first optical energy approaches the ionization volume from a different direction than the first optical energy.

17. The apparatus of claim 14, wherein the first optical energy is provided either continuously or in pulses.

18. The apparatus of claim 1, wherein the first optical energy is focused into a spot of 1 micron in diameter.

19. The apparatus of claim 18, wherein the ionization volume is based on the diameter of the first optical energy and a height of the channel.

20. An apparatus comprising:
a first membrane having a transparent portion;
a second membrane having an aperture;
a channel formed between the first and second membranes;
a gas source coupled to provide gas to the channel; and
first and second optical sources coupled to provide first and second optical energies, respectively, through the transparent portion to excite and ionize the gas to form ions, the ions emitted out of the aperture,
wherein the first optical energy excites the gas to an intermediate energy state, and wherein the second optical energy ionizes the excited gas.
